(19) United States
(12) Patent Application Publication
(10) Pub. No.: US 2025/0292991 A1
(43) Pub. Date: Sep. 18, 2025

(54) SHIELDING FOR IMMERSED PLASMA SOURCE

(71) Applicant: Applied Materials, Inc., Santa Clara, CA (US)

(72) Inventors: Craig ROSSLEE, San Jose, CA (US); Kenneth S. COLLINS, San Jose, CA (US); Oscar LOPEZ, San Jose, CA (US); Tianhong WANG, Sunnyvale, CA (US); Jason A. KENNEY, Campbell, CA (US); Shahid RAUF, Pleasanton, CA (US)

(21) Appl. No.: 18/606,358

(22) Filed: Mar. 15, 2024

(51) Int. Cl. H01J 37/16; H01J 37/32

(52) U.S. Cl. CPC H01J 37/165; H01J 37/3211; H01J 37/32513

(57) ABSTRACT

Embodiments of the disclosure include apparatus which includes a metal shield having a first end, a second end, and an inner bore disposed between the first end and the second end. The inner bore is defined by a wall of the metal shield extending from the first end to the second end. The first end includes an electrically grounded portion. A radio frequency (RF) antenna is disposed at least partially in the inner bore. One or more apertures are formed between the RF antenna and a plasma processing region of a plasma processing chamber. A dielectric material covers the one or more apertures. The RF antenna is configured to deliver RF power to the processing region of the plasma processing chamber through the dielectric material.

### BACKGROUND

### Field

Embodiments described herein generally relate to a system and methods used in semiconductor device manufacturing. More specifically, embodiments of the present disclosure relate to an immersed plasma source used for plasma processing large area substrates.

### Description of the Related Art

Traditional approaches for inductive coupling of power to a plasma formed in a processing region of a plasma processing chamber include the implementation of an externally located current-carrying inductive element (“coil”) placed adjacent to a vacuum-atmosphere structural dielectric window. For large substrates, this approach is problematic as suitable materials (e.g., ceramic) may be expensive or unavailable, the thickness of the dielectric window must be greater, the distance from coil-to-plasma is greater and magnetic mutual coupling is reduced, with high losses versus small substrate processing chamber designs. Scaling up these sources also results in non-uniformities and high capacitive coupling.

To avoid these problems, conventional plasma source designs included inductively coupled elements that were disposed within the processing region of the plasma processing chamber. Components of a plasma processing system that are disposed within the processing region of a plasma processing chamber are subject to numerous conditions which can alter or degrade functionalities of the components. Examples of these conditions include exposure to high temperatures which can cause thermal stresses, exposure to corrosive gases and/or chemicals, particle contamination such as plasma etching byproducts settling on surfaces of the components, and other similar issues. When a component's functionality is altered or degraded, then the component must be repaired or replaced which results in undesirable downtime for the plasma processing system. Furthermore, the alteration or degradation of the component's functionality may not be discovered immediately which can result in processed wafers/substrates of an unacceptable quality.

Accordingly, there is a need in the art for a desirable system that reduces alteration/degradation of component functionality and solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide an apparatus that includes a metal shield having a first end, a second end, and an inner bore disposed between the first end and the second end. The inner bore is defined by a wall of the metal shield extending from the first end to the second end. The first end includes an electrically grounded portion. A radio frequency (RF) antenna is disposed at least partially in the inner bore. One or more apertures are formed between the RF antenna and a plasma processing region of a plasma processing chamber, and a dielectric material covers the one or more apertures. The RF antenna is configured to deliver RF power to the plasma processing region of the plasma processing chamber through the dielectric material.

Embodiments of the present disclosure provide a plasma source that includes a metal shield having a first end, a second end, a wall portion, and a dielectric portion. The wall portion extends from the first end to the second end and is disposed over a substrate support of a plasma processing region of a plasma processing chamber. The first end includes an electrically grounded portion that is grounded within the plasma processing chamber. An electrically conductive rod is disposed over the substrate support and the wall portion. The electrically conductive rod is configured to deliver radio frequency (RF) power to the plasma processing region through the dielectric portion.

Embodiments of the present disclosure provide a method that includes delivering radio frequency (RF) power to an RF antenna disposed in a plasma processing region of a plasma processing chamber. The RF antenna is disposed in an inner bore of a metal shield defined by a wall of the metal shield. A portion of the wall is disposed between the RF antenna and a substrate within the plasma processing region. The RF power is delivered to the plasma processing region through at least one aperture of the metal shield. The substrate is modified based on delivering the RF power to the plasma processing region.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example plasma processing chamber, in accordance with certain embodiments of the present disclosure.

FIG. 1B illustrates a top view of an immersed plasma source, in accordance with certain embodiments of the present disclosure.

FIG. 1C illustrates a schematic representation of a metal etching process, in accordance with certain embodiments of the present disclosure.

FIG. 2 illustrates an example of a shielded immersed plasma source, in accordance with certain embodiments of the present disclosure.

FIGS. 3A and 3B illustrate examples of grounding configurations for a shield of an immersed plasma source, in accordance with certain embodiments of the present disclosure.

FIG. 4 illustrates an example of a shield for an immersed plasma source grounded at first and second ends, in accordance with certain embodiments of the present disclosure.

FIG. 5 illustrates an example arrangement of dielectric containing features within a shield for an immersed plasma source, in accordance with certain embodiments of the present disclosure.

FIG. 6 is a flow diagram illustrating a method for delivering radio frequency (RF) power to a plasma processing region through a shield for an immersed plasma source, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for plasma processing substrates within a plasma processing chamber, which is also referred to herein as a plasma processing system. More specifically, embodiments described herein disclose various shielding configurations for an immersed plasma source. In some embodiments, a radio frequency (RF) antenna (e.g., an electrically conductive rod) is disposed within a sealed processing region of a plasma processing chamber. The RF antenna is configured to deliver RF power supplied by a source RF generator to the processing region. A gas delivery system of the plasma processing chamber delivers one or more gases to the processing region such that delivering the RF power to the processing region ionizes the one or more gases in order to generate and maintain a plasma within the processing region. In some examples, the plasma is generated and maintained for performing a plasma-assisted process (e.g., metal etching) relative to a substrate disposed on a surface of a substrate support within the processing region.

In some embodiments, the immersed plasma source includes an electrically conductive shield that includes a first end, a second end, and an inner bore disposed between the first end and the second end. While not intending to limit the scope of the disclosure provided herein, for simplicity of discussion purposes, the shield is often referred to herein as a metal shield, however, other conductive shielding materials (e.g., metal coated ceramics, metal doped ceramics, graphite, graphene, conductive polymers, etc.) may be used. In one or more embodiments, the inner bore of the metal shield is defined by a wall of the metal shield. In certain embodiments, the first end of the metal shield is electrically grounded within the plasma processing chamber.

In various embodiments, the RF antenna is at least partially disposed in the inner bore of the metal shield. In some embodiments, a dielectric material is disposed between a portion of the RF antenna and the processing region. While not intending to limit the scope of the disclosure provided herein, the dielectric material can include non-conductive materials such as non-conductive polymers, glass, quartz, ceramics, epoxy resins, and/or the like. In one or more embodiments, the metal shield includes an aperture and the dielectric material is disposed over the aperture. In some embodiments, the dielectric material is included in material of an O-ring or a gasket that forms a seal between the inner bore and the one or more gases within the processing region. In various embodiments, a portion of the wall of the metal shield is disposed between the dielectric material and the substrate to be processed.

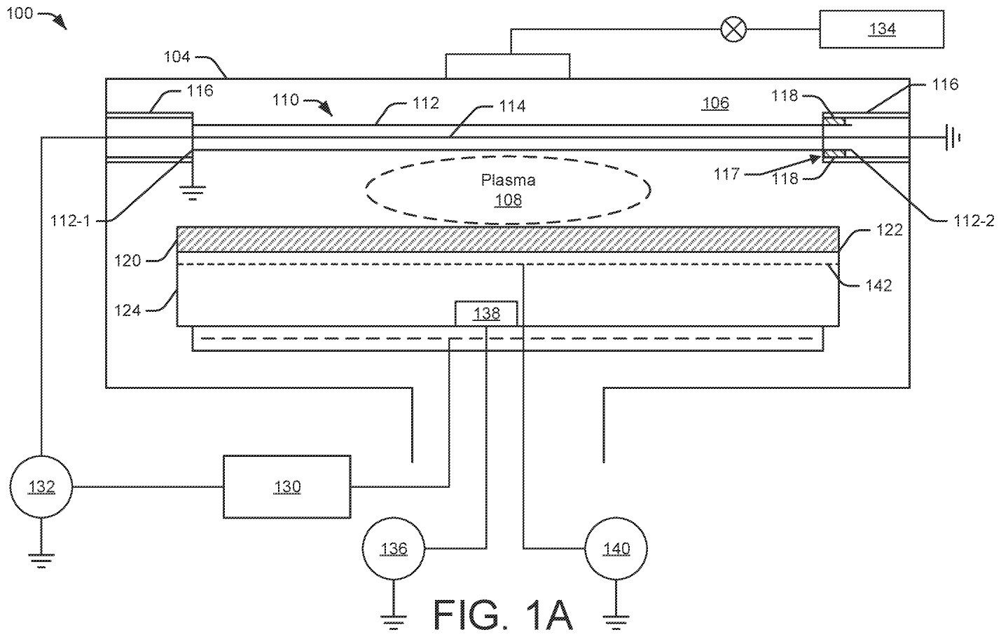

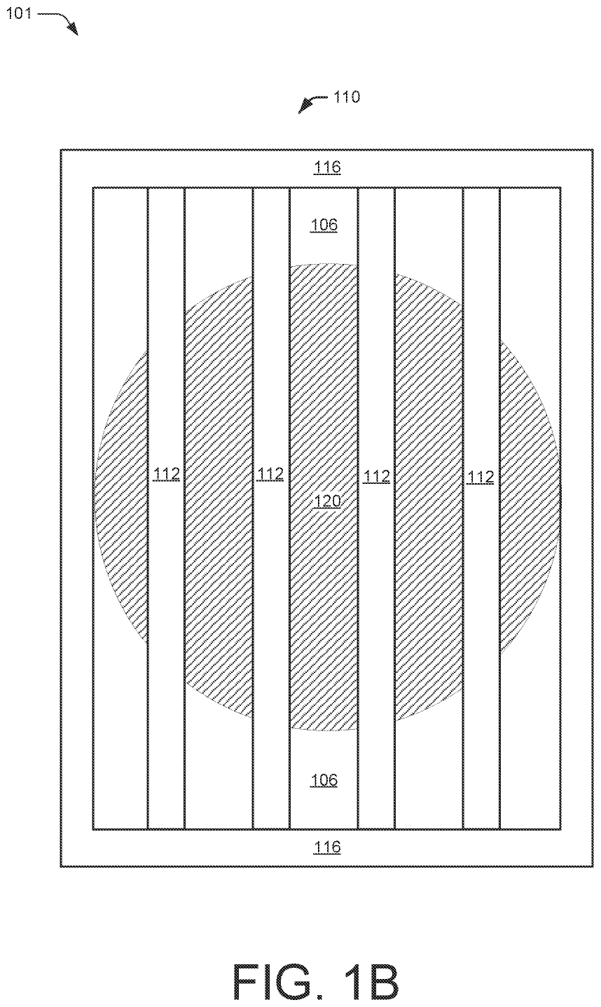

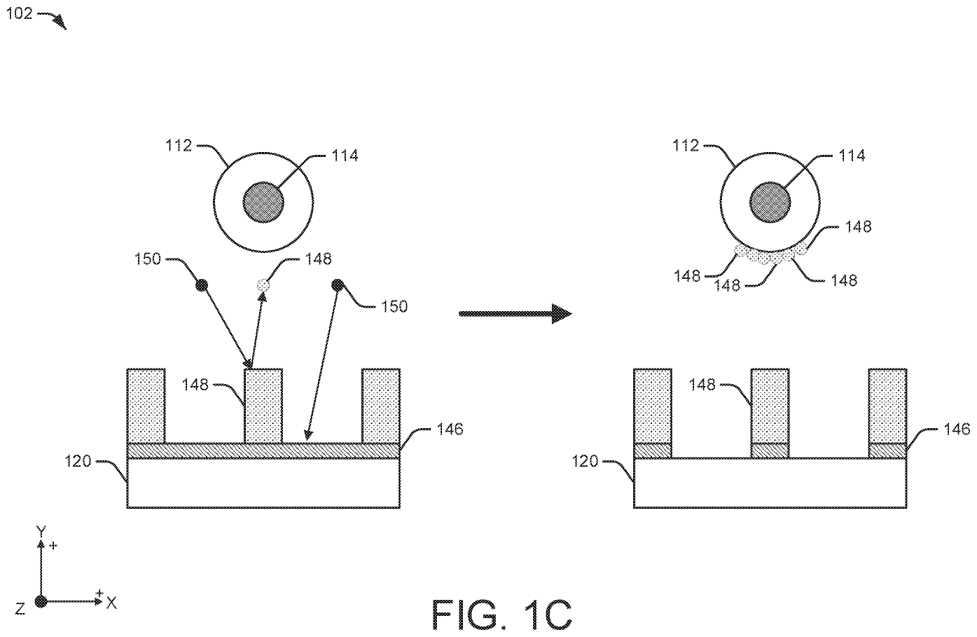

In one or more embodiments, the RF antenna delivers the RF power to the processing region through the dielectric material to generate and maintain a plasma in the processing region. In various embodiments, the plasma-assisted process is performed to deposit a material on or modify a material on the substrate. In some plasma etching examples, the substrate is bombarded with ions as part of the plasma-assisted process. In one example, such as a metal etch process, the plasma generated ions cause material disposed on the substrate (e.g., metal particles) to sputter back towards the RF antenna (FIG. 1C). If the particles of the substrate adhere to a dielectric material containing shield, then the presence of the particles on the shield may cause an undesirable RF coupling shift (e.g., a change in an efficiency or a mode of RF power transfer to the plasma) that will alter the plasma immersion process results performed on different substrates over time. As a result of this undesirable RF coupling change, the immersed plasma source would need to be repaired or replaced resulting in downtime for the plasma processing chamber. In some embodiments, a portion of the wall of the shield prevents the sputtered particles of the substrate from depositing on and adhering to the dielectric material. In one or more embodiments, as described further below, the sputtered particles of the substrate adhere to the portion of the wall of the electrically conductive shield, or metal shield, instead of adhering to a dielectric material containing portion of the metal shield. Notably, the presence of the material removed from the substrate and disposed on the metal shield does not cause an RF coupling shift over time and thus reduces the downtime for the plasma processing chamber.

### Processing System Examples

FIG. 1A is a schematic side cross-sectional view representation of an example plasma processing system 100. In some embodiments, the plasma processing system 100 is configured for plasma-assisted etching processes, such as a reactive ion etch (RIE) plasma processing. The plasma processing system 100 can also be used in other processes such as plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping processing.

The plasma processing system 100 includes a plasma processing chamber 104 which is illustrated to include a processing region 106. A plasma 108 is illustrated below an immersed plasma source 110 in the processing region 106. The immersed plasma source 110 is illustrated to include a metal shield 112 and a radio frequency (RF) antenna 114 disposed in an inner bore of the metal shield 112. In one or more embodiments, the RF antenna 114 includes an electrically conductive rod, such as a copper containing rod.

In some embodiments, the metal shield 112 includes a conductive metal such as a stainless steel, an aluminum alloy, a copper alloy, etc. In some embodiments, the metal shield 112 may include a coating of a conductive material disposed over another material which may or may not be electrically conductive. In certain embodiments, the metal shield 112 includes a material capable of receiving particles of various other materials (e.g., metal particles) which may adhere to the metal shield 112 as a result of various plasma-assisted processes (e.g., metal etching) without altering one or more properties of the plasma processing system 100. In some examples, the metal shield 112 includes a material capable of receiving the particles of the various other materials without shifting an RF coupling (e.g., without changing an efficiency or a mode of RF power transfer to the plasma 108) to the generated plasma 108. For example, the various plasma processing generated particle materials can include the same material as the metal shield 112, or other metal or non-metal materials.

Referring to FIG. 1A, a first end 112-1 of the metal shield 112 is attached to a support 116 and electrically grounded within the processing region 106 of the plasma processing system 100. In various embodiments, a second end 112-2 of the metal shield 112 includes an aperture 117 that is formed between a surface of a support 116 and a surface (e.g., outer surface) of the metal shield 112. In some embodiments, the first and second ends 112-1, 112-2 of the metal shield 112 are disposed in and coupled to supports 116 which secure the immersed plasma source 110 in a position within the processing region 106 of the plasma processing chamber 104.

In various embodiments, a dielectric material 118 is disposed within the aperture 117 and at least between the RF antenna 114 and the processing region 106. The dielectric material 118 includes at least one non-conductive material such as non-conductive polymers, glass, quartz, ceramics, epoxy resins, alumina, or other non-conductive materials. In some embodiments, the dielectric material 118 can include a non-conductive (electrically insulating) coating disposed over another material which may or may not be electrically conductive. In one or more embodiments, the RF antenna 114 delivers RF power to the processing region 106 through the dielectric material 118 in order to generate and maintain the plasma 108 which is illustrated to be disposed between the immersed plasma source 110 and a substrate 120. As shown, the substrate 120 is disposed on a surface 122 of a substrate support 124 within the processing region 106.

In one or more embodiments, the controller 130 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 130 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

In some embodiments, an RF bias generator 136 is electrically coupled to an electrode 138 disposed within the substrate support 124. In some embodiments, the one or more processors of the controller 130 are capable of controlling an RF bias power provided to the electrode 138 by executing instructions that cause the RF bias generator 136 to deliver an RF signal to the electrode 138. In certain embodiments, the RF bias applied by the RF bias generator 136 to the electrode 138 is used to control, for example, energy of plasma generated ions reaching the surface of the substrate 120 during processing.

In some embodiments, a DC voltage source 140 is also electrically coupled to a chucking electrode 142 disposed within the substrate support 124. During plasma processing the one or more processors of the controller 130 can execute instructions which cause the one or more processors to control a DC bias applied to the chucking electrode 142 to cause a voltage to be applied from the DC voltage source 140 to the chucking electrode 142 that is disposed below the surface 122 of the substrate support 124 to electrostatically chuck the substrate to the surface of the substrate support 124. In some embodiments, the DC voltage source 140 is generally capable of outputting example voltages of +/−750 V, +/−1500 V, +/−3000 V, etc. to electrostatically chuck the substrate 120.

The controller 130 is also communicatively coupled (e.g., electrically coupled) to a source RF generator 132. In the example illustrated in FIG. 1A, the source RF generator 132 is electrically coupled to a first end of the RF antenna 114. The second end of the RF antenna is coupled to a ground. In various embodiments, the source RF generator 132 supplies RF power to the RF antenna 114 which the RF antenna 114 delivers to the processing region 106 through the aperture 117 and dielectric material 118 in order to generate and maintain the plasma 108. A center frequency of power supplied by the source RF generator 132 may be from the very low frequency (VLF) to the very high frequency (VHF) band such as, for example, 400 kHz, 2 MHz, 40 MHz, 60 MHz, 120 MHz, or 162 MHz. The supplied power from the source RF generator 132 can be operated in a continuous mode or a pulsed mode. A pulsing frequency of the delivered power from the source RF generator 132 can be from 100 Hz to 10 KHz with duty cycles ranging from 5 percent to 95 percent. The source RF generator 132 has a frequency tuning capability and can adjust its delivered power frequency within e.g., +5 percent or +10 percent. In some embodiments, the source RF generator 132 switches the delivered power frequency at a predefined speed (e.g., two nanoseconds, fifty nanoseconds, etc.).

A gas delivery system 134 is coupled to the processing region 106 of the plasma processing chamber 104. The gas delivery system 134 is configured to deliver at least one processing gas (e.g., argon, nitrogen, oxygen, hydrogen, etc.) to the processing region 106. Depending on the plasma process, the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 134 can include components for activating or energizing one or more processing gases before delivering the processing gases to the processing region 106.

In one or more embodiments, the gas delivery system 134 delivers one or more gases to be ionized to the processing region 106. The one or more processors of the controller 130 execute instructions which cause the one or more processors to control the source RF generator 132 by supplying RF power to the RF antenna 114. In some embodiments, the RF antenna 114 receives the RF power which is not delivered to the processing region 106 through the metal shield 112. Instead, in various embodiments, the RF power is delivered to the processing region 106 through the aperture 117 and dielectric material 118.

The RF power provided from the RF generator 132 induces an electric field which interacts with the ionized atoms or molecules of the gases delivered to the processing region 106 by the gas delivery system 134 causing the charged atoms or molecules to gain energy. Some electrons gain enough energy to break free of atomic orbits of the atoms or molecules which generates free electrons. These energized free electrons collide with neutral gas atoms/molecules causing the atoms/molecules to become ionized by gaining/losing electrons. As a result, the plasma 108 forms as a mixture of free electrons, positive ions, and neutral atoms/molecules.

FIG. 1B illustrates a top view 101 of an immersed plasma source that is disposed over a large area substrate. While FIG. 1B illustrates a round substrate 120 other types of substrates having different substrate shapes (e.g., square, rectangular, etc.) may be processed with the plasma processing system 110. As shown, the immersed plasma source 110 may include multiple metal shields 112 which each contain an RF antenna 114 configured to deliver RF power to the processing region 106 in order to generate and maintain the plasma 108. In some embodiments, each RF antenna 114 is configured to deliver the RF power to the processing region 106 through a dielectric material 118 (not shown). Although four metal shields 112 are illustrated in the top view 101, it is to be understood that the immersed plasma source 110 may include more than four or less than four metal shields 112 in various embodiments.

FIG. 1C illustrates a schematic representation 102 of a metal etching process. In the representation 102, the metal shield 112 and the RF antenna 114 are illustrated as extending in and out of the page (e.g., in the Z direction of FIG. 1C). In this example, the metal shield 112 and the RF antenna 114 are disposed over a portion of the substrate 120 which is enlarged to illustrate a seed metal 146 disposed below copper 148 features. In order to etch the seed metal 146, a surface of the substrate 120 is bombarded with ions 150 that are generated in the plasma 108 formed by providing an RF signal to the RF antenna 114 from the RF generator 132. The ions 150 also cause some of the copper 148 to sputter back towards the metal shield 112 and the RF antenna 114. The sputtered copper 148 accumulates on the metal shield 112 (e.g., the copper 148 coats the metal shield 112). In conventional plasma processing systems having an immersed plasma source, an RF antenna is disposed in a dielectric tube such as a quartz tube. In the conventional systems, the sputtered copper 148 accumulation on the dielectric tube causes an RF coupling shift (e.g., a change in how the RF power is coupled to the plasma) which results in process drift. As a result, the dielectric tube having the accumulated copper 148 needs to be replaced which causes downtime for the conventional plasma processing systems. Unlike the conventional systems, the sputtered copper 148 accumulation on the metal shield 112 does not cause the RF coupling shift. Accordingly, the metal shield 112 does not need to be replaced which avoids downtime for the plasma processing system 100.

### Shielding for Immersed Plasma Source Examples

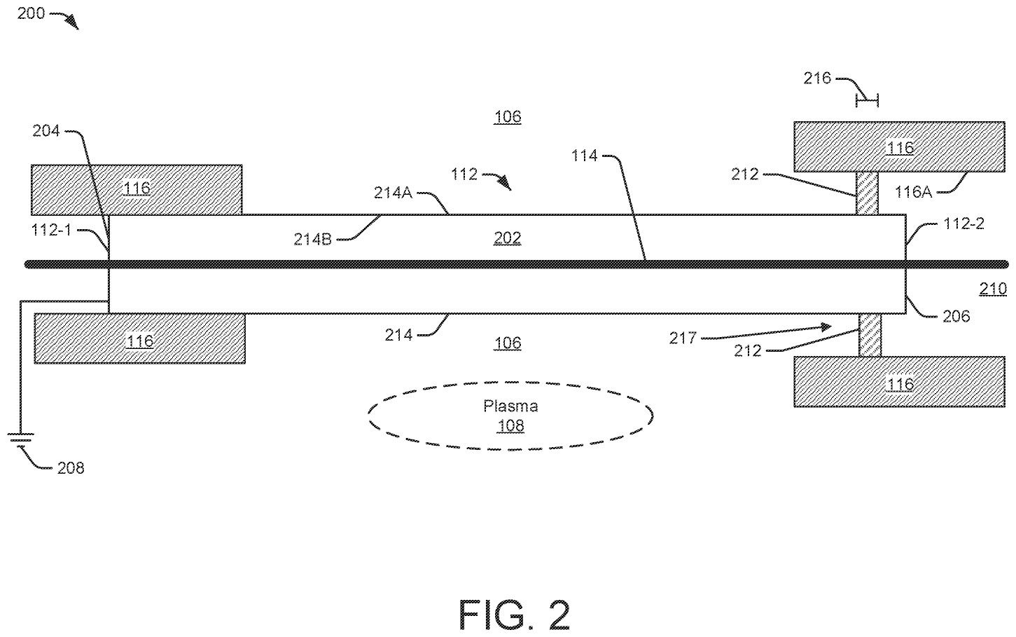

FIG. 2 illustrates an example 200 of a shielded immersed plasma source. As shown, the metal shield 112 includes an inner bore 202 having a first end 204 and a second end 206. The RF antenna 114 is disposed in the inner bore 202 such that the RF antenna extends out from the first end 204 and the second end 206. In some embodiments, the first end 112-1 of the metal shield 112 is disposed within a support 116 and is electrically grounded 208 and the second end 112-1 is disposed within a support 116 but isolated from a grounded surface. In some embodiments, the inner bore 202 and region 210 surrounding the first end 112-1 and second end 112-2 are in communication with a vacuum or non-vacuum environment that is not in fluid communication with the processing region 106.

At the second end 112-2 a dielectric material 212 is disposed over a portion of an outer surface 214A of a wall 214 of the metal shield 112 and between an inner surface 116A of a support 116. In one or more embodiments, the inner bore 202 is defined by an inner surface 214B of the wall 214 of the metal shield 112. In some embodiments, the wall 214 has a thickness in a range of about 1 millimeter to about 4 millimeters such as 2 millimeters. In other embodiments, the thickness of the wall 214 is less than 1 millimeter or greater than 4 millimeters.

In some embodiments, the dielectric material 212 is included in a material of an O-ring or a gasket having a thickness 216 in a range of about 1 millimeter to about 4 millimeters such as 2.5 millimeters. In other embodiments, the dielectric material 212 is included in the material of the O-ring or the gasket having the thickness 216 of less than 1 millimeter or greater than 4 millimeters. In certain embodiments, the dielectric material 212 forms a seal between the region 210 within the supports 116 and the processing region 106.

In various embodiments, the RF power supplied to the RF antenna 114 by the source RF generator 132 is delivered to the processing region 106 through an aperture 217 in which the dielectric material 212 is disposed in order to generate and maintain the plasma 108. In the illustrated example in FIG. 2, sputtered metal particles from the substrate 120 such as the copper 148 are not able to deposit on the dielectric material 212, since the dielectric material 212 is disposed within a portion of the supports 116. In some embodiments, the dielectric material 212 is hidden from a line of sight to the surface of the substrate. In some embodiments, the sputtered metal particles from the substrate 120 such as the copper 148 may adhere to the metal shield 112 and, due to the electrical conductivity of the metal shield 112, will not cause an RF coupling shift over time due to the deposition of a conductive layer that includes the sputtered metal particles.

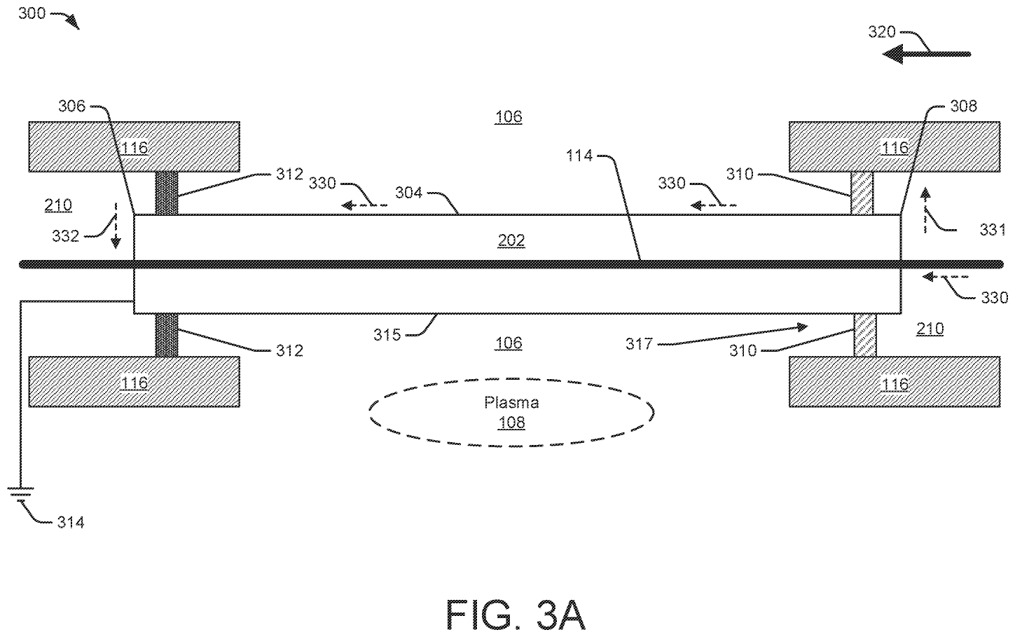

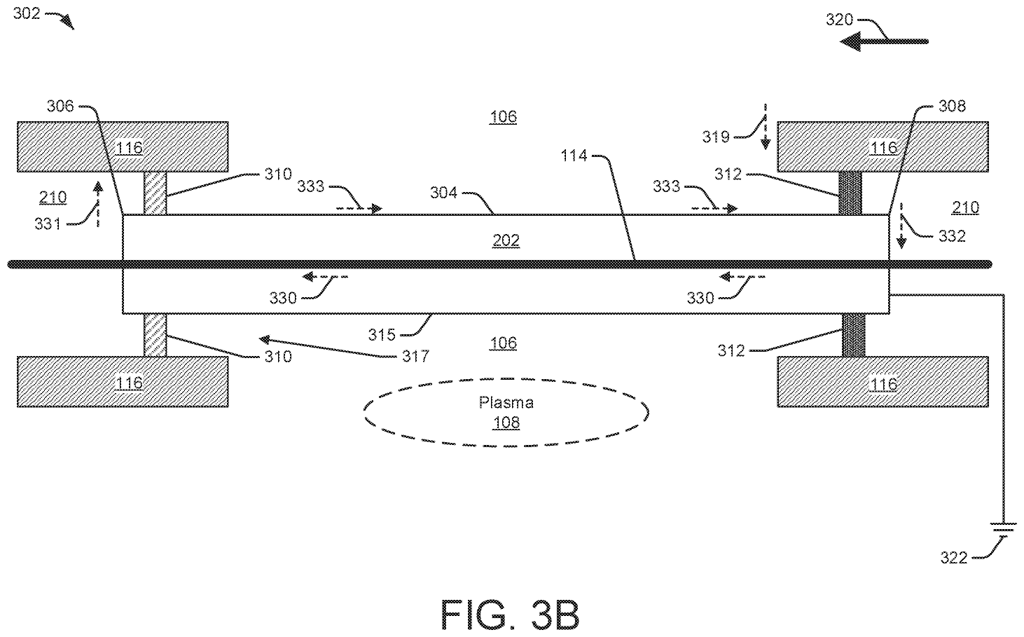

FIGS. 3A and 3B illustrate examples of grounding configurations for a shield of an immersed plasma source. FIG. 3A illustrates a representation 300 of an example of a left side grounding configuration. In the representation 300, a metal shield 304 (e.g., a metal tube) includes a first end 306, a second end 308, and the inner bore 202 disposed between the first end 306 and the second end 308. The RF antenna 114 is disposed in the inner bore 202 and extends from the first end 306 and the second end 308 of the metal shield 304. In various embodiments, RF power supplied to the RF antenna 114 by the RF source generator 132 is delivered to the processing region 106 through one or more apertures 317 that include a dielectric material 310 in order to generate and maintain the plasma 108.

In some embodiments, the dielectric material 310 is disposed between a first portion of the metal shield 304 (e.g. a wall 315 of the metal shield 304) and the a support 116 at a first position along the metal shield 304 that is closer to the second end 308 than the first end 306. In one or more embodiments, the dielectric material 310 is included in a material of an O-ring or a gasket. In certain embodiments, the dielectric material 310 forms a first seal between the region 210 within the supports 116 and the processing region 106.

In certain embodiments, a metal ring 312 is disposed between a second portion of the metal shield 304 (e.g., the wall 315 of the metal shield 304) and a support 116 at a second position along the metal shield 304 that is closer to the first end 306 than the second end 308. Although described as a metal ring 312, the metal ring 312 may also include a non-metal electrically conductive material. In one or more embodiments, the metal ring 312 forms a second seal between the region 210 within the supports 116 and the processing region 106. In various embodiments, the first end 306 is electrically grounded 314 within the processing region 106 of the plasma processing system 100.

In some embodiments, based on a launch direction 320 of the one or more gasses to be ionized to generate and maintain the plasma 108, current initially flows through the RF antenna 114 in a first direction 330. The current then flows through the dielectric material 310 in a second direction 331. Next, the current flows through the wall 315 in the first direction 330. Finally, the current flows through the metal ring 312 in a third direction 332.

FIG. 3B illustrates a representation 302 of an example of a right side grounding configuration. Like the representation 300 of FIG. 3A, the representation 302 includes the metal shield 304 and the RF antenna 114 disposed in the inner bore 202. The representation 302 also includes the dielectric material 310 disposed between the second portion of the metal shield 304 and the supports 116 at the second position along the metal shield 304. As shown, metal ring 312 is disposed between the first portion of the metal shield 304 and the supports 116 at the first position along the metal shield 304.

Unlike the representation 300 of FIG. 3A in which the first end 306 is electrically grounded 314, in the representation 302 of FIG. 3B, the second end 308 is electrically grounded 322 within the processing region 106 of the plasma processing system 100. In some embodiments, based on the launch direction 320, current initially flows through the RF antenna 114 in the first direction 330. The current then flows through the dielectric material 310 in the second direction 331. Next, the current flows through the wall 315 in a fourth direction 333. Finally, the current flows through the metal ring 312 in the third direction 332.

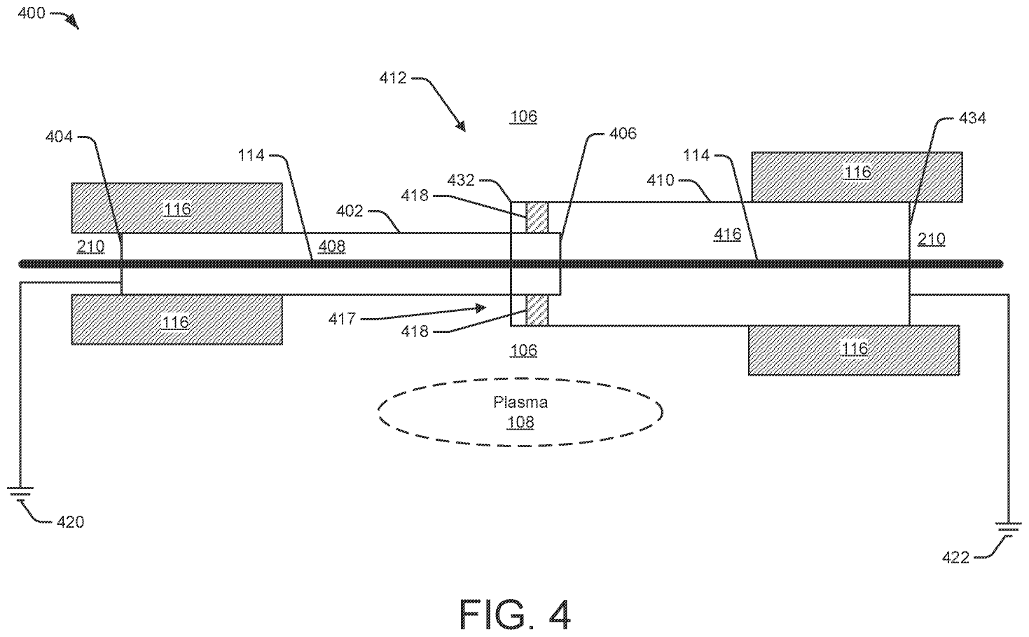

FIG. 4 illustrates an example 400 of a shield for an immersed plasma source grounded at the first and second ends of a metal shield 412. As shown, the example 400 includes an inner metal tube 402 which has a first end 404, a second end 406, and an inner bore 408 disposed between the first end 404 and the second end 406. In some embodiments, the inner metal tube 402 is at least partially disposed in a portion of an outer metal tube 410. The outer metal tube 410 is illustrated to include a first end 432, a second end 434, and an inner bore 416 disposed between the first end 432 and the second end 434. A portion of the inner metal tube 402 (e.g., the first end 404) is supported by a support 116 and a portion of the outer metal tube 410 (e.g., the second end 434) is supported by a support 116.

In one or more embodiments, the RF antenna 114 is disposed in the inner bore 408 and the inner bore 416 such that a first portion of the RF antenna 114 extends from the first end 404 and a second portion of the RF antenna 114 extends out from the second end 434. In various embodiments, a dielectric material 418 is disposed in the inner bore 416 and around a portion of the inner metal tube 402. In some embodiments, the dielectric material 418 is included in material of an O-ring or a gasket such that the dielectric material 418 forms a seal between the inner bore 416 and the processing region 106.

In certain embodiments, the first end 404 of the inner metal tube 402 is electrically grounded 420. In one or more embodiments, the second end 434 of the outer metal tube 410 is electrically grounded 422. In various embodiments, RF power supplied to the RF antenna 114 by the RF source generator 132 is delivered to the processing region 106 through an aperture 417 that includes the dielectric material 418 in order to generate and maintain the plasma 108. Since the dielectric material 418 is disposed within the inner bore 416, the dielectric material 418 is not at risk of receiving metal particles that may be sputtered into the processing region 106 as a result of a plasma-assisted process which could cause an RF coupling shift due to the sputtered particles blocking the RF generated electric fields generated by RF biasing the antenna 114. Notably, the inner metal tube 402 and the outer metal tube 410 are not at risk of causing an RF coupling shift even if the inner metal tube 402 and/or the outer metal tube 410 receive the sputtered metal particles on their outer (e.g., plasma facing) surfaces.

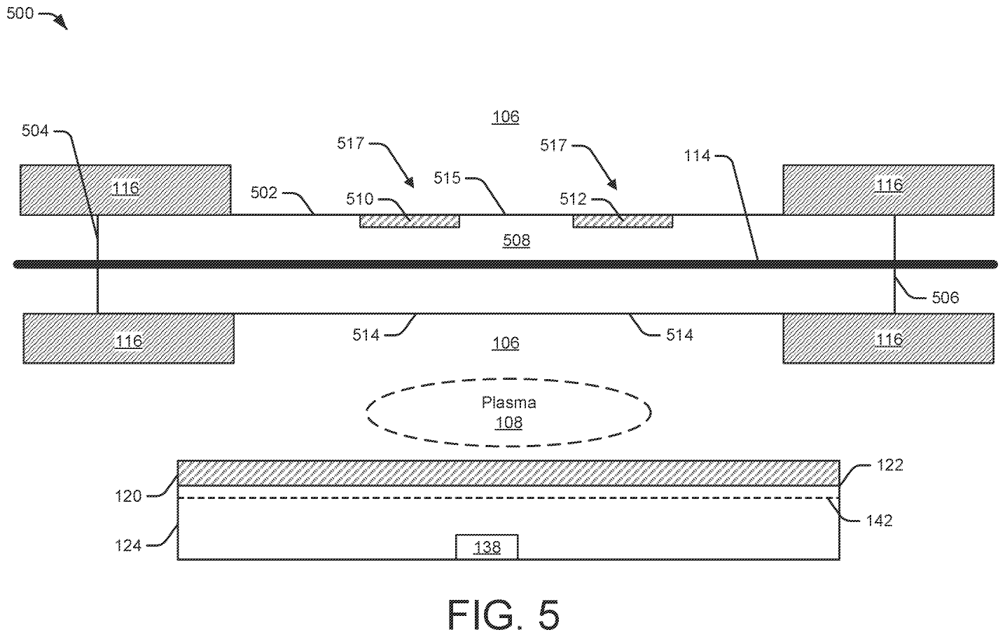

FIG. 5 illustrates an example arrangement 500 of dielectric containing features within a shield for an immersed plasma source. As shown, the example arrangement 500 includes a metal shield 502 having a first end 504, a second end 506, and an inner bore 508 disposed between the first end 504 and the second end 506. In some embodiments, the inner bore 508 is defined by a wall 515 of the metal shield 502. In the illustrated example, a first portion of the metal shield 502 (e.g., the first end 504) is supported by a support 116 and a second portion of the metal shield 502 (e.g., the second end 506) is supported by a support 116.

The RF antenna 114 is disposed in the inner bore 508 such that the RF antenna 114 extends from the first end 504 and also extends from the second end 506. In some embodiments, a first dielectric portion 510 is disposed over a first aperture of apertures 517 in the metal shield 502. In various examples, the wall 515 of the metal shield 502 is discontinuous between the first end 504 and the second end 506. In one or more embodiments, a second dielectric portion 512 is disposed over a second aperture of the apertures 517 in the metal shield 502.

As shown in FIG. 5, a wall portion 514 of the wall 515 of the metal shield 502 is disposed between the substrate 120 and the antenna 114. In various embodiments, RF power is supplied to the RF antenna 114 by the source RF generator 132. In one or more embodiments, the RF antenna 114 is configured to deliver the RF power to the processing region 106 through the first dielectric portion 510 and/or the second dielectric portion 512 covering the apertures 517 in order to generate and maintain the plasma 108. In various embodiments, the substrate 120 is modified based on delivering the RF power to the processing region 106 through the apertures 517 that include the first dielectric portion 510 and/or the second dielectric portion 512. In some examples such as the example representation 102 of metal etching shown in FIG. 1C, the surface of the substrate 120 is bombarded with the ions 150 which cause particles of the substrate 120, such as the copper 148, to sputter back towards the RF antenna 114 and the wall portion 514.

If the sputtered particles of the substrate 120 adhere to the first dielectric portion 510 or the second dielectric portion 512, the presence of the sputtered particles of the substrate 120 can cause an RF coupling shift. Since the wall portion 514 faces the substrate 120 and the first and second dielectric portions 510, 512 face away from the substrate 120 the sputtered particles of the substrate 120 will adhere to the wall portion 514 instead of the first and second dielectric portions 510, 512, due to the dielectric portions 510, 512 not having a direct line-of-sight to the substrate surface. In various embodiments, the presence of the sputtered particles of the substrate 120 on the wall portion 514 does not cause an RF coupling shift.

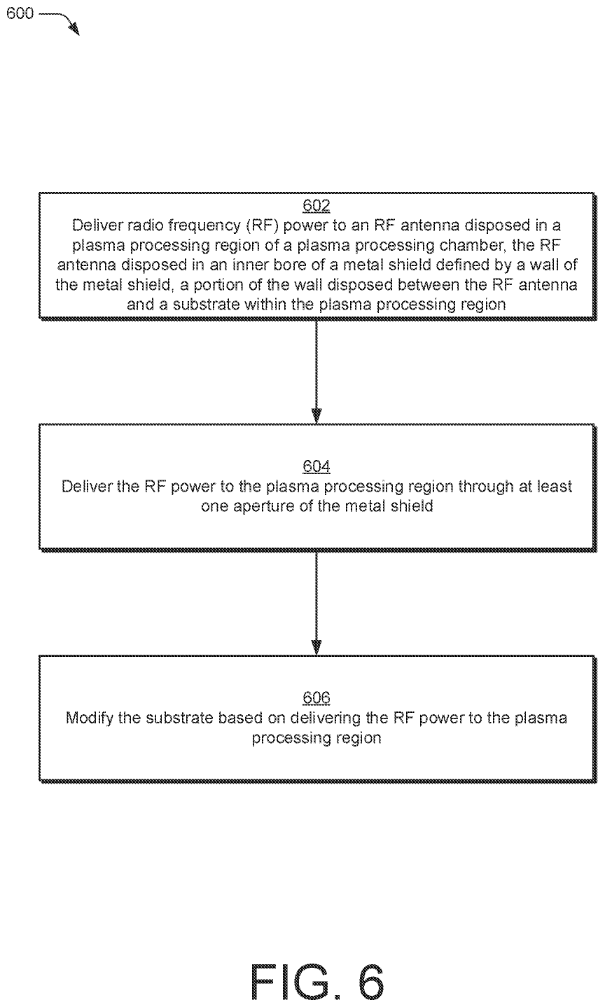

FIG. 6 is a flow diagram illustrating a method 600 for delivering radio frequency (RF) power to a plasma processing region through a shield for an immersed plasma source. At 602, RF power is delivered to an RF antenna disposed in a plasma processing region of a plasma processing chamber, the RF antenna is disposed in an inner bore of a metal shield defined by a wall of the metal shield, a portion of the wall is disposed between the RF antenna and a substrate within the plasma processing region. In one or more embodiments, the RF antenna 114 is disposed in an inner bore of the metal shield 112, 304, 402, 410, 502 and a wall portion is disposed between the substrate 120 and the RF antenna 114.

At 604, the RF power is delivered to the plasma processing region through at least one aperture of the metal shield. In some embodiments, the RF power is delivered to the processing region 106 through at least one of the dielectric materials 118, 212, 310, 418, the first dielectric portion 510, or the second dielectric portion 512.

At 606, the substrate is modified based on delivering the RF power to the plasma processing region. In various embodiments, the substrate 120 is modified based on delivering the RF power to the processing region 106 through at least one aperture of the metal shield 112, 304, 402, 410, 502 by biasing the RF antenna 114.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. An apparatus comprising:
a metal shield having a first end, a second end, and an inner bore disposed between the first end and the second end, the inner bore defined by a wall of the metal shield extending from the first end to the second end;
an electrically grounded portion of the first end of the metal shield;
a radio frequency (RF) antenna disposed at least partially within the inner bore of the metal shield;
one or more apertures formed between the RF antenna and a plasma processing region of a plasma processing chamber; and
a dielectric material disposed over the one or more apertures,
wherein the RF antenna is configured to deliver RF power to the processing region of the plasma processing chamber through the dielectric material.

2. The apparatus of claim 1, wherein the dielectric material is disposed between the inner bore and the plasma processing region.

3. The apparatus of claim 1, wherein the metal shield comprises a metal tube.

4. The apparatus of claim 1, wherein the wall extends at least partially around the RF antenna.

5. The apparatus of claim 4, wherein the inner bore is defined by a cylindrical inner surface of the wall.

6. The apparatus of claim 1, further comprising an additional electrically grounded portion of the second end of the metal shield.

7. The apparatus of claim 6, wherein the one or more apertures are disposed between the electrically grounded portion of the first end and the additional electrically grounded portion of the second end.

8. The apparatus of claim 1, wherein the wall is continuous between the first end and the second end.

9. The apparatus of claim 1, wherein the wall is discontinuous between the first end and the second end.

10. The apparatus of claim 1, wherein the wall includes an outer metal tube and an inner metal tube at least partially disposed in the outer metal tube, the inner bore includes a first inner bore of the outer metal tube and a second inner bore of the inner metal tube.

11. The apparatus of claim 1, wherein the one or more apertures are included in the second end.

12. The apparatus of claim 1, wherein the dielectric material is a material included in of at least one of an O-ring or a gasket.

13. The apparatus of claim 1, wherein the dielectric material is included in a seal between the inner bore and the plasma processing region.

14. A plasma source comprising:
a metal shield having a first end, a second end, a wall portion, and a dielectric portion, the wall portion extending from the first end to the second end and disposed over a substrate support disposed within a plasma processing region of a plasma processing chamber;
an electrically grounded portion of the first end of the metal shield, the electrically grounded portion grounded within the plasma processing chamber; and
an electrically conductive rod disposed over the substrate support and the wall portion, the electrically conductive rod configured to deliver radio frequency (RF) power to the plasma processing region through the dielectric portion.

15. The plasma source of claim 14, wherein the dielectric portion includes a seal between an inner bore of the metal shield and the plasma processing region.

16. The plasma source of claim 15, wherein the dielectric portion covers an aperture in the wall portion.

17. The plasma source of claim 15, wherein the wall portion includes an outer metal tube and an inner metal tube at least partially disposed in the outer metal tube, the inner bore includes a first inner bore of the outer metal tube and a second inner bore of the inner metal tube.

18. The plasma source of claim 17, further comprising an additional electrically grounded portion of the second end of the metal shield.

19. The plasma source of claim 14, wherein the dielectric portion includes at least one of an O-ring or a gasket.

20. A method comprising:
delivering radio frequency (RF) power to an RF antenna disposed in a plasma processing region of a plasma processing chamber, the RF antenna disposed in an inner bore of a metal shield defined by a wall of the metal shield, a portion of the wall disposed between the RF antenna and a substrate within the plasma processing region;
delivering the RF power to the plasma processing region through at least one aperture of the metal shield; and
modifying the substrate based on delivering the RF power to the plasma processing region.
